(19) United States
(12) Patent Application Publication
(10) Pub. No.: US 2020/0035670 A1
(43) Pub. Date: Jan. 30, 2020

(54) ELECTROSTATIC DISCHARGE PROTECTION APPARATUS FOR INTEGRATED CIRCUIT

(71) Applicant: Faraday Technology Corp., Hsinchu (TW)

(72) Inventors: Chia-Ku Tsai, Hsinchu (TW); Chi-Sheng Liao, Hsinchu (TW); Jeng-Huang Wu, Hsinchu (TW)

(73) Assignee: Faraday Technology Corp., Hsinchu (TW)

(21) Appl. No.: 16/153,829

(22) Filed: Oct. 8, 2018

(30) Foreign Application Priority Data
Jul. 27, 2018 (TW) 107126011

(51) Int. Cl. H01L 27/02; H02H 9/04

(52) U.S. Cl. CPC H01L 27/0288; H01L 27/0266; H01L 29/866; H01L 27/0292; H02H 9/046

(57) ABSTRACT

A electrostatic discharge (ESD) protection apparatus for an integrated circuit (IC) is provided. A first electrostatic current rail and a second electrostatic current rail of the ESD protection apparatus do not directly connected to any bonding pad of the IC. The ESD protection apparatus further includes a clamp circuit and four ESD protection circuits. The clamp circuit is coupled between the first electrostatic current rail and the second electrostatic current rail. A first ESD protection circuit is coupled between the first electrostatic current rail and a signal pad of the IC. A second ESD protection circuit is coupled between the signal pad and the second electrostatic current rail. A third ESD protection circuit is coupled between a first power rail and the second electrostatic current rail. A fourth ESD protection circuit is coupled between the second electrostatic current rail and a second power rail.

### CROSS-REFERENCE TO RELATED APPLICATION

This application claims the priority benefits of Taiwan application serial no. 107126011, filed on Jul. 27, 2018. The entirety of the above-mentioned patent application is hereby incorporated by reference herein and made a part of this specification.

### BACKGROUND OF THE DISCLOSURE

### Field of the Disclosure

The disclosure relates to a semiconductor device, and in particular relates to an electrostatic discharge protection apparatus for an integrated circuit.

### Description of Related Art

Generally speaking, electrostatic discharge (ESD) protection devices are usually disposed in the integrated circuit to prevent the internal circuit of the integrated circuit from being damaged by ESD current. For example, an ESD protection device can be disposed between a power rail and a signal pad in the integrated circuit to instantly discharge a large amount of ESD current. When a positive ESD pulse occurs on the signal pad, the ESD protection device instantly directs the ESD current of the signal pad to the power rail. When a negative ESD pulse occurs on the signal pad, the ESD protection device can extract current from the power rail and guide the current to the signal pad.

When the integrated circuit is in normal operation, in order to reduce leakage current flowing through the ESD protection device, conventional integrated circuits typically dispose a plurality of ESD protection devices connected in series between the power rail and the signal pad. However, the more ESD protection devices are connected in series, the higher the threshold voltage the ESD protection devices are triggered to turn on, and thereby the ESD protection devices are unable to effectively protect the internal circuit of the conventional integrated circuit.

Therefore, it is necessary to provide a new ESD protection architecture that can reduce the leakage current generated during normal operation of the integrated circuit without affecting the capability of the ESD protection devices.

### SUMMARY OF THE DISCLOSURE

The disclosure provides an electrostatic discharge protection apparatus for an integrated circuit. The electrostatic discharge protection apparatus can provide a whole-chip ESD protection for integrated circuits while maintaining a low leakage current during normal operation of the integrated circuit.

An embodiment of the disclosure provides an electrostatic discharge (ESD) protection apparatus for an integrated circuit. The ESD protection apparatus of the integrated circuit comprises a first electrostatic current rail, a second electrostatic current rail, a first ESD protection circuit, a second ESD protection circuit, a third ESD protection circuit, a fourth ESD protection circuit, and a first clamp circuit. The first electrostatic current rail and the second electrostatic current rail are not directly connected to any bonding pad of the integrated circuit. A first end and a second end of the first ESD protection circuit are respectively coupled to the first electrostatic current rail and a signal pad of the integrated circuit. A first end and a second end of the second ESD protection circuit are respectively coupled to the signal pad and the second electrostatic current rail. A first end and a second end of a third ESD protection circuit are respectively coupled to a first power rail of the integrated circuit and the second electrostatic current rail. A first end and a second end of the fourth ESD protection circuit are respectively coupled to the second electrostatic current rail and a second power rail of the integrated circuit. A first end and a second end of the first clamp circuit are respectively coupled to the first electrostatic current rail and the second electrostatic current rail.

Based on the above, in embodiments of the disclosure, the first electrostatic current rail and the second electrostatic current rail of the ESD protection apparatus are not directly connected to any bonding pad of the integrated circuit. Therefore, the first electrostatic current rail and the second electrostatic current rail may be regarded as being in a floating state. Because the first electrostatic current rail and the second electrostatic current rail are in the floating state (i.e., not directly coupled to any voltage source), almost no leakage current flows through the first ESD protection circuit and/or the second ESD protection circuit from a signal pad of an integrated circuit under normal operation of the integrated circuit. Because it is not required to consider the leakage current of the ESD protection circuits in the present disclosure, only a small number of ESD protection elements (such as diodes or transistors) are needed to be disposed in these ESD protection circuits and clamp circuits. In an ESD protection circuit (or a clamp circuit), the fewer ESD protection elements are connected in series, the lower the threshold voltage the ESD protection elements (or clamp circuits) are triggered to turn on, so that the ESD protection circuits of the ESD protection apparatus in the disclosure can provide good ESD protection.

In order to make the above features and advantages of the disclosure more obvious and understandable, several embodiments accompanied with figures are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a circuit block diagram illustrating an ESD protection apparatus applied to an integrated circuit according to an embodiment of the disclosure.

FIG. 2 is a circuit diagram illustrating the first ESD protection circuit and the second ESD protection circuit of FIG. 1 according to an embodiment of the disclosure.

FIG. 3A-3B are circuit diagrams illustrating a clamp circuit of FIG. 1 in accordance with various embodiments of the disclosure.

FIG. 4A-4B are circuit diagrams illustrating a third ESD protection circuit and a fourth ESD protection circuit of FIG. 1 in accordance with various embodiments of the disclosure.

FIG. 5 is a circuit block diagram illustrating an ESD protection apparatus applied to an integrated circuit having a plurality of chips according to another embodiment of the disclosure.

### DESCRIPTION OF EMBODIMENTS

The term “coupled (or connected)” as used throughout the specification (including the claims) may refer to any direct or indirect connecting means. For example, if the first device is described as being coupled (or connected) to the second device, it should be interpreted that the first device can be directly connected to the second device, or the first device can be indirectly connected to the second device through other devices or certain connecting means. In addition, when applicable, devices/components/steps that use the same reference numerals in the figures and embodiments represent the same or similar parts. Devices/components/steps that use the same reference numerals or use the same terms in different embodiments can be cross-referenced.

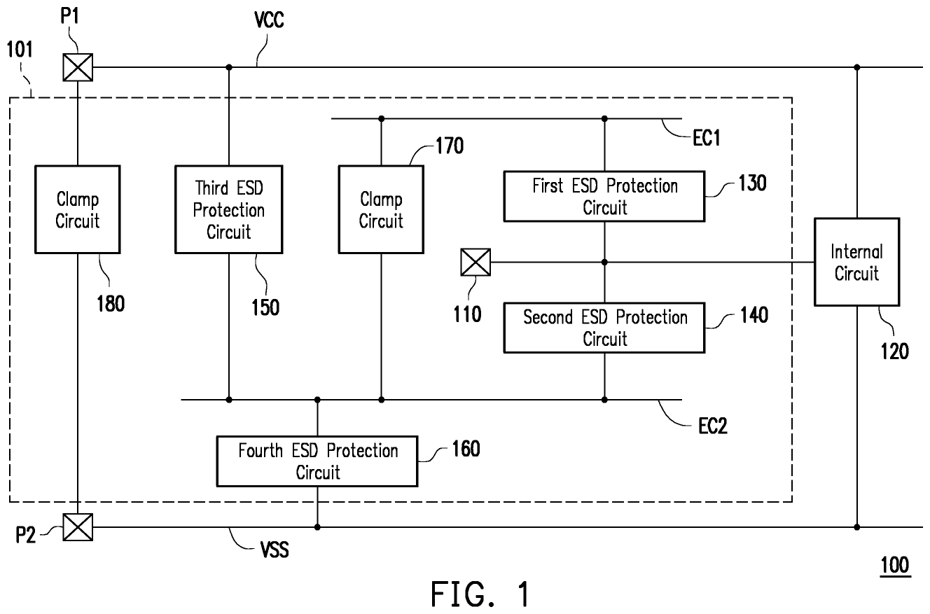

FIG. 1 is a circuit block diagram illustrating an ESD protection apparatus applied to an integrated circuit according to an embodiment of the disclosure. Please refer to FIG. 1, the integrated circuit 100 includes a signal pad 110, an internal circuit 120, a first power rail VCC, a second power rail VSS, a power pad P1, a power pad P2, and an electrostatic discharge (ESD) protection apparatus 101. In the embodiment shown in FIG. 1, the ESD protection apparatus 101 includes a first electrostatic current rail EC1, a second electrostatic current rail EC2, a first ESD protection circuit 130, a second ESD protection circuit 140, a third ESD protection circuit 150, a fourth ESD protection circuit 160, a clamp circuit 170 and a clamp circuit 180. The first end and the second end of the clamp circuit 180 are respectively coupled to the first power rail VCC and the second power rail VSS. According to design requirements, the clamp circuit 180 shown in FIG. 1 can be a conventional ESD clamp circuit or other ESD clamp circuit, and therefore no description will be further provided hereinafter.

As shown in FIG. 1, the signal pad 110 is coupled to the internal circuit 120. The internal circuit 120 represents a core circuit and/or a functional circuit of the integrated circuit 100. The first power rail VCC and the second power rail VSS are directly connected to the power pad P1 and the power pad P2, respectively, to transmit power to the internal circuit 120. In this embodiment, the first power rail VCC can be a system voltage rail, and the second power rail VSS can be a ground voltage rail. The first electrostatic current rail EC1 and the second electrostatic current rail EC2 are not directly connected to any bonding pad of the integrated circuit 100. For example, the signal pad 110, the power pad P1 and the power pad P2 are not directly connected to the first electrostatic current trail EC1 or directly connected to the second electrostatic current trail EC2.

The first end and the second end of the first ESD protection circuit 130 are respectively coupled to the first electrostatic current rail EC1 and the signal pad 110. The first end and the second end of the second ESD protection circuit 140 are respectively coupled to the signal pad 110 and the second electrostatic current rail EC2. The first end and the second end of the third ESD protection circuit 150 are respectively coupled to the first power rail VCC and the second electrostatic current rail EC2. The first end and the second end of the fourth ESD protection circuit 160 are respectively coupled to the second electrostatic current rail EC2 and the second power rail VSS. The first end and the second end of the clamp circuit 170 are respectively coupled to the first electrostatic current rail EC1 and the second electrostatic current rail EC2.

When the integrated circuit 100 is performed in a normal operating mode, the first electrostatic current rail EC1 and the second electrostatic current rail EC2 are in a floating state, that is, the first electrostatic current rail EC1 and the second electrostatic current rail EC2 are not directly coupled to any voltage source. Therefore, almost no leakage current flows through the first ESD protection circuit 130 and/or the second ESD protection circuit 140 from the signal pad 110 under the normal operating mode.

In addition, when a positive ESD pulse occurs on the signal pad 110, assuming that the power pad P1 is grounded, the ESD current can be directed from the signal pad 110 to the power pad P1 via a discharge path formed by the first ESD protection circuit 130, the first electrostatic current rail EC1, the clamp circuit 170, the second electrostatic current rail EC2, the third ESD protection circuit 150, and the first power rail VCC. When the ESD current occurs, assuming that the power pad P2 is grounded, the ESD current can be directed from the signal pad 110 to the power pad P2 via a discharge path formed by the first ESD protection circuit 130, the first electrostatic current rail EC1, the clamp circuit 170, the second electrostatic current rail EC2, the fourth ESD protection circuit 160, and the second power rails VSS.

On the other hand, when a negative ESD pulse occurs on the signal pad 110, assuming that the power pad P2 is grounded, the ESD current can be directed from the power pad P2 to the signal pad 110 via a discharge path formed by the second power rail VSS, the fourth ESD protection circuit 160, the second electrostatic current rail EC2, and the second ESD protection circuit 140. When the ESD current occurs, assuming that the power pad P1 is grounded, the ESD current can be directed from the power pad P1 to the signal pad 110 via a discharge path formed by the first power rail VCC, the clamp circuit 180, the second power rail VSS, the fourth ESD protection circuit 160, the second electrostatic current rail EC2, and the second ESD protection circuit 140. Therefore, the internal circuit 120 can be protected, which prevents from burning out the internal circuit 120 by the ESD current.

The first ESD protection circuit 130, the second ESD protection circuit 140, the third ESD protection circuit 150, the fourth ESD protection circuit 160, and/or the clamp circuit 170 can be any type of ESD element/circuit. For example, the first ESD protection circuit 130 of FIG. 1 may include a diode circuit, and the second ESD protection circuit 140 can include another diode circuit. The first end and the second end of the diode circuit of the first ESD protection circuit 130 are respectively coupled to the first electrostatic current rail EC1 and the signal pad 110. The first end and the second end of the diode circuit of the second ESD protection circuit 140 are respectively coupled to the signal pad 110 and the second electrostatic current rail EC2. According to design requirements, the diode circuit of the first ESD protection circuit 130 can include at least one diode, at least one diode string, at least one transistor, and/or other ESD elements/circuits, and the diode circuit of the second ESD protection circuit 140 may include at least one diode, at least one diode string, at least one transistor, and/or other ESD elements/circuits.

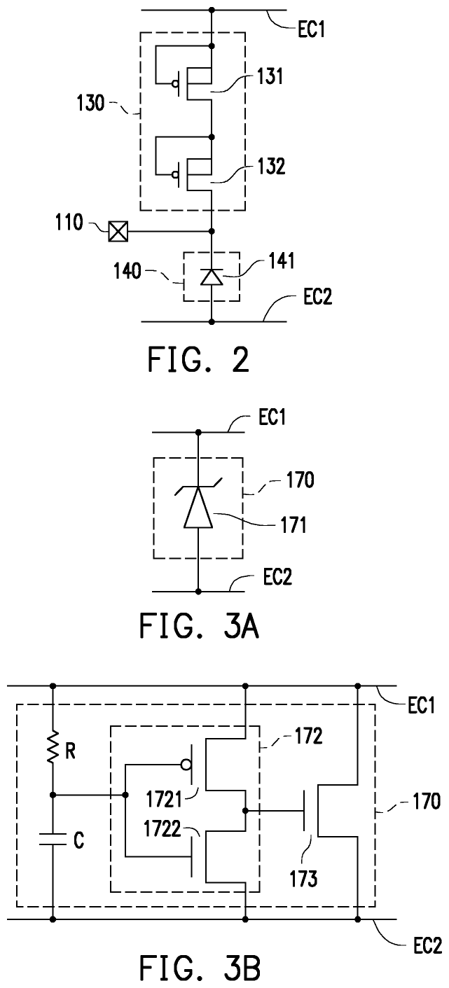

For example, FIG. 2 is a circuit diagram illustrating the first ESD protection circuit 130 and the second ESD protection circuit 140 of FIG. 1 according to an embodiment of the disclosure. Please refer to FIG. 2, the diode circuit of the first ESD protection circuit 130 includes a transistor 131 and a transistor 132. The first terminal (e.g., the source) and the control terminal (e.g., the gate) of the transistor 131 are coupled to the first electrostatic current rail EC1. The first terminal (e.g., the source) and the control terminal (e.g., the gate) of the transistor 132 is coupled to the second terminal of the transistor 131 (e.g., the drain), and the second terminal of the transistor 132 (e.g., the drain) is coupled to the signal pad 110. It will be noted that although the transistor 131 and the transistor 132 shown in FIG. 2 are P-Channel Metal-Oxide-Semiconductor (PMOS) transistors, the transistor 131 and/or the transistor 132, in other embodiments, may be other types of transistors. In some embodiments, according to design requirements, the transistor 131 and/or the transistor 132 can be replaced with a diode or other ESD element. The number of transistors (or diodes) disposed in the first ESD protection circuit 130 can be adjusted according to actual design requirements.

In the embodiment shown in FIG. 2, the diode circuit of the second ESD protection circuit 140 includes a diode 141. The first end of the diode 141 (e.g., the cathode) is coupled to the signal pad 110, and the second end of the diode 141 (e.g., the anode) is coupled to the second electrostatic current rail EC2. It will be noted that, according to design requirements, the diode 141 can be replaced with a transistor (referring to the related description of the transistor 131 and/or the transistor 132) or other ESD element. The number of diodes (or transistors) disposed in the second ESD protection circuit 140 can be adjusted according to actual design requirements. For example, the diode circuit of the second ESD protection circuit 140 may include a diode string, and the diode string includes a plurality of diodes connected in series.

FIG. 3A-3B are circuit diagrams illustrating the clamp circuit 170 of FIG. 1 in accordance with various embodiments of the disclosure. In the embodiment shown in FIG. 3A, the clamp circuit 170 includes a Zener Diode 171. The first end of the Zener diode 171 (e.g., the cathode) is coupled to the first electrostatic current rail EC1, and the second end of the Zener diode 171 (e.g., the anode) is coupled to the second electrostatic current rail EC2. The clamp circuit 170 is provided with the Zener diode 171, and therefore the Zener diode 171 can form a stable clamping voltage between the first electrostatic current rail EC1 and the second electrostatic current rail EC2 when the electrostatic current flow from the first electrostatic current rail EC1 to the second electrostatic current rail EC2.

The clamp circuit 170 of FIG. 1 can also be implemented by a passive element with an active element. For example, in the embodiment shown in FIG. 3B, the clamp circuit 170 includes a resistor R, a capacitor C, a NOT gate 172, and a transistor 173. The first end of the resistor R is coupled to the first electrostatic current rail EC1. The first end of the capacitor C is coupled to the second end of the resistor R, and the second end of the capacitor C is coupled to the second electrostatic current rail EC2. The input terminal of the NOT gate 172 is coupled to the second end of the resistor R. The first terminal of the transistor 173 (e.g., the drain) is coupled to the first electrostatic current rail EC1, the control terminal (e.g., the gate) of the transistor 173 is coupled to the output terminal of the NOT gate 172, the second terminal (e.g., the source) of the transistor 173 is coupled to the second electrostatic current rail EC2.

In the embodiment of FIG. 3B, the NOT gate 172 includes a transistor 1721 and a transistor 1722. The first terminal (e.g., the source) of the transistor 1721 is coupled to the first electrostatic current rail EC1, and the control terminal (e.g., a gate) of the transistor 1721 is coupled to the second end of the resistor R. The first terminal of the transistor 1722 (e.g., the drain) and the second terminal of the transistor 1721 (e.g., the drain) are coupled to the control terminal of the transistor 173. The control terminal (e.g., the gate) of the transistor 1722 is coupled to the second end of the resistor R, and the second terminal (e.g., the source) of the transistor 1722 is coupled to the second electrostatic current rail EC2.

The third ESD protection circuit 150 shown in FIG. 1 may include a diode circuit, and the fourth ESD protection circuit 160 shown in FIG. 1 may include another diode circuit. The first end and the second end of the diode circuit of the third ESD protection circuit 150 are respectively coupled to the first power rail VCC and the second electrostatic rail EC2, and the first end and the second end of a diode circuit of the fourth ESD protection circuit 160 are respectively coupled to the second electrostatic current rail EC2 and the second power rail VSS. According to design requirements, the diode circuit of the third ESD protection circuit 150 can include at least one diode, at least one diode string, at least one transistor, and/or other ESD elements/circuits, and the diode circuit of the fourth ESD protection circuit 160 may include at least one diode, at least one diode string, at least one transistor, and/or other ESD elements/circuits.

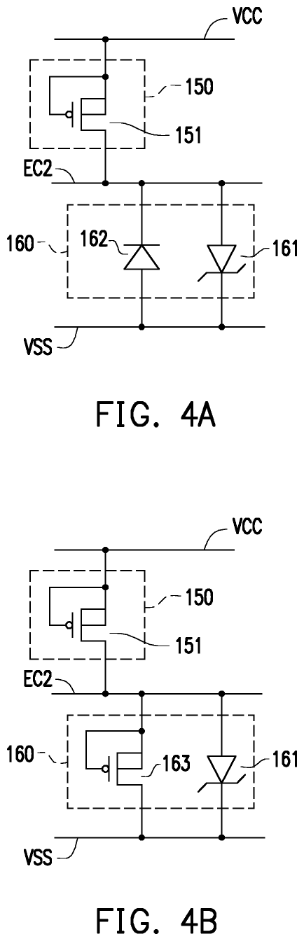

For example, FIG. 4A-4B are circuit diagrams illustrating the third ESD protection circuit 150 and the fourth ESD protection circuit 160 of FIG. 1 in accordance with various embodiments of the disclosure. In the embodiment shown in FIG. 4A, the diode circuit of the third ESD protection circuit 150 includes a transistor 151. The first terminal (e.g., the source) and the control terminal (e.g., the gate) of the transistor 151 are coupled to the first power rail VCC, and the second terminal of the transistor 151 (e.g., the drain) is coupled to the second electrostatic current rail EC2. It will be noted that although the transistor 151 shown in FIG. 4A is a PMOS transistor, the transistor 151, in other embodiment, can be other type of transistor. In some embodiments, according to design requirements, the transistor 151 can be replaced with a diode or other ESD element. The number of transistors (or diodes) disposed in the third ESD protection circuit 150 can be adjusted according to actual design requirements.

The fourth ESD protection circuit 160 shown in FIG. 4A includes a Zener diode 161 and a diode 162. The first end of the Zener diode 161 (e.g., the anode) is coupled to the second electrostatic current rail EC2, and the second end of the Zener diode 161 (e.g., the cathode) is coupled to the second power rail VSS. The first end of the diode 162 (e.g., the cathode) is coupled to the second electrostatic current rail EC2, and the second end of the diode 162 (e.g., the anode) is coupled to the second power rail VSS. Please refer to FIG. 1 and FIG. 4A, when the positive ESD pulse occurs on the signal pad 110, the Zener diode 161 of the fourth ESD protection circuit 160 will be turned on, so that the ESD current can be directed to the second power rail VSS via a discharge path formed by the first ESD protection circuit 130, the clamp circuit 170 and the Zener diode 161.

When a negative ESD pulse occurs on the signal pad 110, the diode 162 of the fourth ESD protection circuit 160 will be turned on, so that the ESD current can be directed from the second power rail VSS to the signal pad 110 via a discharge path formed by the diode 162 and the second ESD protection circuit 140; or the ESD current can be directed from the first power rail VCC to the signal pad 110 via a discharge path formed by the clamp circuit 180, the diode 162, and the second ESD protection circuit 140.

Different from the embodiment shown in FIG. 4A, the fourth ESD protection circuit 160 shown in FIG. 4B includes a Zener diode 161 and a transistor 163. Referring to FIG. 4B, the anode of the Zener diode 161 is coupled to the second electrostatic current rail EC2, and the cathode of the Zener diode 161 is coupled to the second power rail VSS. The first terminal (e.g., the source) and the control terminal (e.g., the gate) of the transistor 163 are coupled to the second electrostatic current rail EC2, and the second end of the transistor 163 (e.g., the drain) is coupled to the second power rail VSS. The ESD protection operation details for the fourth ESD protection circuit 160 shown in FIG. 4B can be deduced from the related descriptions for the fourth ESD protection circuit 160 shown in FIG. 4A, and therefore no description will be further provided hereinafter.

It will be noted that although the transistor 163 shown in FIG. 4B is a PMOS transistor, the transistor 163, in other embodiment, can be other type of transistor. For example, in some embodiments, the transistor 163 may be an N-Channel Metal-Oxide-Semiconductor (NMOS) transistor, and the first terminal (e.g., the drain) of the NMOS transistor is coupled to the second electrostatic current rail EC2, and the second terminal (e.g., the source) and the control terminal (e.g., the gate) of the NMOS transistor is coupled to the second power rail VSS. In other embodiments, according to design requirements, the transistor 163 can be replaced with a diode or other ESD element. The number of transistors and/or diodes disposed in the fourth ESD protection circuit 160 can be adjusted according to actual design requirements.

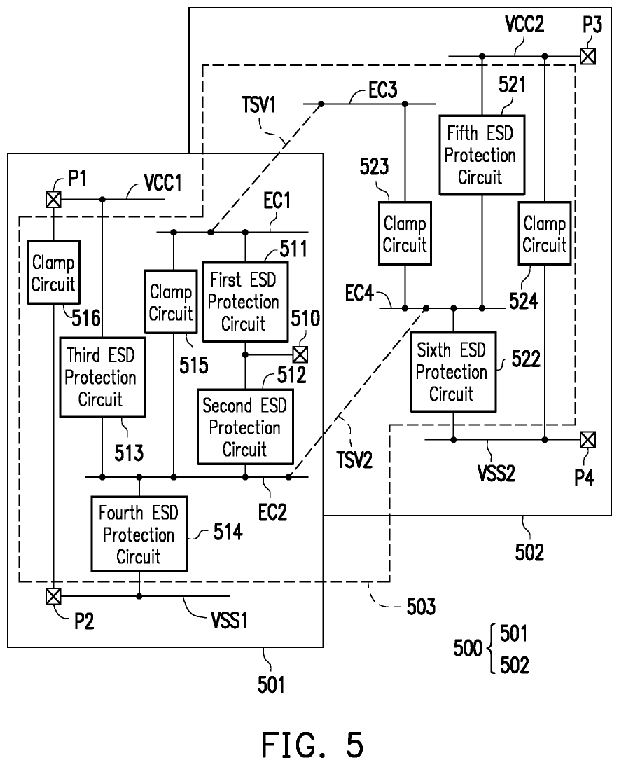

FIG. 5 is a circuit block diagram illustrating an ESD protection apparatus 503 applied to an integrated circuit 500 having a plurality of chips in accordance with another embodiment of the disclosure. The integrated circuit 500 shown in FIG. 5 may include circuits for different power domains. For example, the integrated circuit 500 can include a first chip 501 and a second chip 502, and the first chip 501 and the second chip 502 may have different operating voltage according to their chip functions. For example, the input/output circuit of the integrated circuit 500 can be disposed on the first chip 501, and the operating voltage of the first chip 501 can be 3.3V. The logic operation circuit of the integrated circuit 500 can be disposed on the second chip 502, the operating voltage of the second chip 502 can be 1.8V.

The ESD protection apparatus 503 includes a first electrostatic current rail EC1, a second electrostatic current rail EC2, a third electrostatic current rail EC3, a fourth electrostatic current rail EC4, a first ESD protection circuit 511, and a second ESD protection circuit 512, a third ESD protection circuit 513, a fourth ESD protection circuit 514, a fifth ESD protection circuit 521, a sixth ESD protection circuit 522, a clamp circuit 515, a clamp circuit 516, a clamp circuit 523, and a clamp circuit 524. For the sake of simplicity, the internal circuit of the integrated circuit 500 is not shown in FIG. 5. As shown in FIG. 5, the first chip 501 of the integrated circuit 500 includes a signal pad 510, a first electrostatic current rail EC1, a second electrostatic current rail EC2, a first power rail VCC1, a second power rail VSS1, a power pad P1, power pad P2, a first ESD protection circuit 511, a second ESD protection circuit 512, a third ESD protection circuit 513, a fourth ESD protection circuit 514, a clamp circuit 515, and a clamp circuit 516.

The first power rail VCC1 and the second power rail VSS1 are directly connected to the power pad P1 and the power pad P2, respectively, for transmitting power to the internal circuit (not shown) of the first chip 501. In this embodiment, the first power rail VCC1 may be a system voltage rail, and the second power rail VSS1 may be a ground voltage rail. The first electrostatic current rail EC1 and the second electrostatic current rail EC2 are not directly connected to any bonding pad of the integrated circuit 500. For example, the signal pad 510, the power pad P1 and the power pad P2 are not directly connected to the first electrostatic current rail EC1 or directly connected to the second electrostatic current rail EC2.

The ESD protection operation details for the first electrostatic current rail EC1, the second electrostatic current rail EC2, the first ESD protection circuit 511, the second ESD protection circuit 512, the third ESD protection circuit 513, the fourth ESD protection circuit 514, the clamp circuit 515 and the clamp circuit 516 shown in FIG. 5 can be deduced from the related descriptions for the first electrostatic current rail EC1, the second electrostatic current rail EC2, the first ESD protection 130, the second ESD protection circuit 140, the third ESD protection circuit 150, the fourth ESD protection circuit 160, the clamp circuit 170 and the clamp circuit 180 illustrated in FIG. 1, FIG. 2, FIG. 3A, FIG. 3B, FIG. 4A and/or FIG. 4B, and therefore no description will be further provided hereinafter.

The second chip 502 of the integrated circuit 500 includes a third electrostatic current rail EC3, a fourth electrostatic current rail EC4, a third power rail VCC2, a fourth power rail VSS2, a power pad P3, a power pad P4, the fifth ESD protection circuit 521, the sixth ESD protection circuit 522, the clamp circuit 523, and the clamp circuit 524. The third power rail VCC2 and the fourth power rail VSS2 are directly connected to the power pad P3 and the power pad P4, respectively, for transmitting power to the internal circuit (not shown) of the second chip 502. In this embodiment, the third power rail VCC2 can be a system voltage rail, and the fourth power rail VSS2 can be a ground voltage rail.

As shown in FIG. 5, the third electrostatic current rail EC3 of the second chip 502 is not directly connected to any bonding pad of the integrated circuit 500, and the third electrostatic current rail EC3 can be electrically connected to the first electrostatic current rail EC1 of the first chip 501 via a through-substrate via (TSV) TSV1. The fourth electrostatic current rail EC4 of the second chip 502 is also not directly connected to any bonding pad of the integrated circuit 500, and the fourth electrostatic current rail EC4 can be electrically connected to the second electrostatic current rail EC2 via another through-substrate via TSV2.

The first end and the second end of the fifth ESD protection circuit 521 are respectively coupled to the third power rail VCC2 and the fourth electrostatic current rail EC4. The first end and the second end of the sixth ESD protection circuit 522 are respectively coupled to the fourth electrostatic current rail EC4 and the fourth power rail VSS2. The first end and the second end of the clamp circuit 523 are respectively coupled to the third electrostatic current rail EC3 and the fourth electrostatic current rail EC4. The first end and the second end of the clamp circuit 524 are respectively coupled to the third power rail VCC2 and the fourth power rail VSS2. The ESD protection operation details for the third electrostatic current rail EC3, the fourth electrostatic current rail EC4, the fifth ESD protection circuit 521, the sixth ESD protection circuit 522, and the clamp circuit 523 shown in FIG. 5 can be deduced from the related descriptions for the first electrostatic current rail EC1, the second electrostatic current rail EC2, the third ESD protection circuit 150, the fourth ESD protection circuit 160 and the clamp circuit 170 illustrated in FIG. 1, FIG. 3A, FIG. 3B, FIG. 4A and/or FIG. 4B, and therefore no description will be further provided hereinafter. In addition, according to design requirements, the clamp circuit 524 shown in FIG. 5 can be a conventional ESD clamp circuit or other ESD clamp circuit.

It is assumed that the power pad P3 of the second chip 502 is grounded. When the positive ESD pulse occurs on the signal pad 510 of the first chip 501, the ESD current may be directed from the signal pad 510 to the power pad P3 via a discharge path formed by the first ESD protection circuit 511, the first electrostatic current rail EC1, the through-substrate via TSV1, the third electrostatic current rail EC3, the clamp circuit 523, the fourth electrostatic current rail EC4, the fifth ESD protection circuit 521 and the third power rail VCC2. When ESD current occurs on the signal pad 510 of the first chip 501, assuming that the power pad P4 of the second wafer 502 is grounded, the ESD current may be directed from the signal pad 510 of the first chip 501 to the power pad P4 via a discharge path formed by the first ESD protection circuit 511, the first electrostatic current rail EC1, the through-substrate via TSV1, the third electrostatic current rail EC3, the clamp circuit 523, the fourth electrostatic current rail EC4, the sixth ESD protection circuit 522 and the fourth power rail VSS2.

It is assumed that the power pad P4 of the second chip 502 is grounded. When a negative ESD pulse occurs on the signal pad 510 of the first chip 501, the ESD current may be directed from the power pad P4 to the signal pad 510 via the discharge path formed by the fourth power rail VSS2, the sixth ESD protection circuit 522, the fourth electrostatic current rail EC4, the through-substrate via TSV2, the second electrostatic current rail EC2, and the second ESD protection circuit 512. It is assumed that the power pad P3 of the second chip 502 is grounded. When a negative ESD pulse occurs on the signal pad 510 of the first chip 501, the ESD current may be directed from the power pad P3 of the second chip 502 to the signal pad 510 via a discharge path formed by the third power rail VCC2, the clamp circuit 524, the fourth power rail VSS2, the sixth ESD protection circuit 522, the fourth electrostatic current rail EC4, the through-substrate via TSV2, the second electrostatic current rail EC2, and the second ESD protection circuit 512. Therefore, the internal circuit (not shown) of the integrated circuit 500 can be protected, which prevents from burning out the internal circuit by the ESD current.

In summary, in embodiments of the disclosure, the first electrostatic current rail and the second electrostatic current rail of the ESD protection apparatus are not directly connected to any bonding pad of the integrated circuit. Therefore, the first electrostatic current rail and the second electrostatic current rail may be regarded as being in a floating state. Because the first electrostatic current rail and the second electrostatic current rail are in the floating state (i.e., not directly coupled to any voltage source), almost no leakage current flows through the first ESD protection circuit and/or the second ESD protection circuit from a signal pad of an integrated circuit under normal operation of the integrated circuit. Because it is not required to consider the leakage current of the ESD protection circuits in the present disclosure, only a small number of ESD protection elements (such as diodes or transistors) are needed to be disposed in these ESD protection circuits and clamp circuits. In an ESD protection circuit (or a clamp circuit), the fewer ESD protection elements are connected in series, the lower the threshold voltage the ESD protection elements (or clamp circuits) are triggered to turn on, so that the ESD protection circuits of the ESD protection apparatus in the disclosure can provide good ESD protection.

Although the disclosure has been disclosed by the above embodiments, it will be apparent to those skilled in the art that various modifications to the described embodiments can be made without departing from the scope or spirit of the disclosure. Therefore, the scope of the disclosure will be defined by the attached claims and not by the above detailed descriptions.

What is claimed is:

1. An electrostatic discharge protection apparatus for an integrated circuit, comprising:
a first electrostatic current rail, wherein the first electrostatic current rail is not directly connected to any bonding pad of the integrated circuit;
a first electrostatic discharge protection circuit, having a first end and a second end respectively coupled to the first electrostatic current rail and a signal pad of the integrated circuit;
a second electrostatic current rail, wherein the second electrostatic current rail is not directly connected to any bonding pad of the integrated circuit;
a second electrostatic discharge protection circuit, having a first end and a second end respectively coupled to the signal pad and the second electrostatic current rail;
a first clamp circuit, having a first end and a second end respectively coupled to the first electrostatic current rail and the second electrostatic current rail;
a third electrostatic discharge protection circuit, having a first end and a second end respectively coupled to a first power rail of the integrated circuit and the second electrostatic current rail; and
a fourth electrostatic discharge protection circuit, having a first end and a second end respectively coupled to the second electrostatic current rail and a second power rail of the integrated circuit.

2. The electrostatic discharge protection apparatus according to claim 1, wherein the first power rail is a system voltage rail, and the second power rail is a ground voltage rail.

3. The electrostatic discharge protection apparatus according to claim 1, wherein the first electrostatic discharge protection circuit comprises:
a diode circuit, wherein a first end of the diode circuit is coupled to the first electrostatic current rail, and a second end of the diode circuit is coupled to the signal pad.

4. The electrostatic discharge protection apparatus according to claim 3, wherein the diode circuit comprises a diode or a diode string.

5. The electrostatic discharge protection apparatus according to claim 3, wherein the diode circuit comprises:
at least one transistor, having a first terminal, a second terminal and a control terminal, wherein the first terminal of the at least one transistor and the control terminal are both coupled to the first electrostatic current rail, and the second terminal of the at least one transistor is coupled to the signal pad.

6. The electrostatic discharge protection apparatus according to claim 1, wherein the second electrostatic discharge protection circuit comprises:
a diode circuit, a first end of the diode circuit is coupled to the signal pad, a second end of the diode circuit is coupled to the second electrostatic current rail.

7. The electrostatic discharge protection apparatus according to claim 6, wherein the diode circuit comprises a diode or a diode string.

8. The electrostatic discharge protection apparatus according to claim 1, wherein the first clamp circuit comprises:
a Zener diode, wherein a cathode of the Zener diode is coupled to the first electrostatic current rail, and an anode of the Zener diode is coupled to the second electrostatic current rail.

9. The electrostatic discharge protection apparatus according to claim 1, wherein the first clamp circuit comprises:
a resistor, wherein a first end of the resistor is coupled to the first electrostatic current rail;
a capacitor, wherein a first end of the capacitor is coupled to a second end of the resistor, and a second end of the capacitor is coupled to the second electrostatic current rail;
a NOT gate, wherein an input terminal of the NOT gate is coupled to the second end of the resistor; and
a transistor, wherein a first end of the transistor is coupled to the first electrostatic current rail, a control terminal of the transistor is coupled to an output terminal of the NOT gate, and a second terminal of the transistor is coupled to the second electrostatic current rail.

10. The electrostatic discharge protection apparatus according to claim 1, wherein the third electrostatic discharge protection circuit comprises:
a diode circuit, wherein a first end of the diode circuit is coupled to the first power rail, and a second end of the diode circuit is coupled to the second electrostatic current rail.

11. The electrostatic discharge protection apparatus according to claim 10, wherein the diode circuit comprises a diode or a diode string.

12. The electrostatic discharge protection apparatus according to claim 1, the fourth electrostatic discharge protection circuit comprising:
a Zener diode, wherein an anode of the Zener diode is coupled to the second electrostatic current rail, and a cathode of the Zener diode is coupled to the second power rail; and
a diode, wherein a cathode of the diode is coupled to the second electrostatic current rail, and an anode of the diode is coupled to the second power rail.

13. The electrostatic discharge protection apparatus according to claim 1, further comprising:
a second clamp circuit, having a first end and a second end respectively coupled to the first power rail and the second power rail.

14. The electrostatic discharge protection apparatus according to claim 1, wherein the first electrostatic current rail, the second electrostatic current rail, the first electrostatic discharge protection circuit, the second electrostatic discharge protection circuit, the first clamp circuit, the first power rail, the second power rail, the third electrostatic discharge protection circuit and the fourth electrostatic discharge protection circuit are configured on a first chip, and the electrostatic discharge protection apparatus further comprises:
a third electrostatic current rail, configured on a second chip, wherein the third electrostatic current rail is not directly connected to any bonding pad of the integrated circuit, and the third electrostatic current rail is electrically connected to the first electrostatic current rail via a first through-substrate via;
a fourth electrostatic current rail, configured on the second chip, wherein the fourth electrostatic current rail is not directly connected to any bonding pad of the integrated circuit, and the fourth electrostatic current rail is electrically connected to the second electrostatic current rail via a second through-substrate via;
a second clamp circuit, having a first end and a second end respectively coupled to the third electrostatic current rail and the fourth electrostatic current rail, wherein the second clamping circuit is configured on the second chip;
a fifth electrostatic discharge protection circuit, configured on the second chip, wherein a first end and a second end of the fifth electrostatic discharge protection circuit are respectively coupled to a third power rail of the integrated circuit and the fourth electrostatic current rail, and the third power rail is configured on the second chip; and
a sixth electrostatic discharge protection circuit, configured on the second chip, wherein a first end and a second end of the sixth electrostatic discharge protection circuit are respectively coupled to the fourth electrostatic current rail and a fourth power rail of the integrated circuit, and the fourth power rail is configured on the second chip.

15. The electrostatic discharge protection apparatus according to claim 14, further comprising:
a third clamp circuit, configured on the second chip, wherein a first end and a second end of the third clamp circuit are respectively coupled to the third power rail and the fourth power rail.
